(19) United States
(12) Patent Application Publication
(10) Pub. No.: US 2024/0215229 A1
(43) Pub. Date: Jun. 27, 2024

(54) SEMICONDUCTOR DEVICE

(71) Applicant: Samsung Electronics Co., Ltd., Suwon-si (KR)

(72) Inventors: MINSUNG KANG, Suwon-si (KR); WONHEE CHO, Suwon-si (KR); HYOUNGYOL MUN, Suwon-si (KR); SUNGDONG CHO, Suwon-si (KR)

(21) Appl. No.: 18/224,546

(22) Filed: Jul. 20, 2023

(30) Foreign Application Priority Data
Dec. 21, 2022 (KR) 10-2022-0180927

(51) Int. Cl. H10B 12/00

(52) U.S. Cl. CPC H10B 12/50; H10B 12/01; H10B 12/315

(57) ABSTRACT

A semiconductor device may include a semiconductor layer on a substrate, a first insulating layer on the semiconductor layer, a first conductive structure, which is provided to penetrate the first insulating layer in a vertical direction perpendicular to a bottom surface of the substrate and is connected to the semiconductor layer, a second insulating layer covering the first insulating layer and the first conductive structure, a second conductive structure, which is provided to penetrate the second insulating layer in the vertical direction and is connected to the first conductive structure, and a diffusion barrier layer covering a top surface of the first insulating layer and extending to a side surface of the first conductive structure. The lowermost surface of the second conductive structure may be located at a height higher than the top surface of the first insulating layer.

### CROSS-REFERENCE TO RELATED APPLICATION(S)

This U.S. non-provisional patent application claims priority under 35 U.S.C. § 119 to Korean Patent Application No. 10-2022-0180927, filed on Dec. 21, 2022, in the Korean Intellectual Property Office, the disclosure of which is hereby incorporated by reference in its entirety.

### BACKGROUND

The present disclosure relates to a semiconductor device, and in particular, to a semiconductor device including conductive structures.

Due to their small-sized, multifunctional, and/or low-cost characteristics, semiconductor devices are being esteemed as important elements in the electronic industry. The semiconductor devices are classified into a semiconductor memory device for storing data, a semiconductor logic device for processing data, and a hybrid semiconductor device including both of memory and logic elements.

Due to the recent increasing demand for electronic devices with a fast speed and/or low power consumption, the semiconductor devices are needed to have fast operating speeds and/or low operating voltages, while also being miniaturized to accommodate the shrinking size of electronic devices. As a result, various research efforts are underway to improve the electrical and reliability characteristics of semiconductor devices, while also producing more highly integrated semiconductor devices.

### SUMMARY

Example embodiments of the inventive concept provide a semiconductor device with improved electrical and reliability characteristics.

According to an embodiment of the inventive concept, a semiconductor device may include a semiconductor layer on a substrate, a first insulating layer on the semiconductor layer, a first conductive structure, which is provided to penetrate the first insulating layer in a vertical direction perpendicular to a bottom surface of the substrate and is connected to the semiconductor layer, a second insulating layer covering the first insulating layer and the first conductive structure, a second conductive structure, which is provided to penetrate the second insulating layer in the vertical direction and is connected to the first conductive structure, and a diffusion barrier layer covering a top surface of the first insulating layer and extending to a side surface of the first conductive structure. The lowermost surface of the second conductive structure may be located at a height higher than the top surface of the first insulating layer.

According to an embodiment of the inventive concept, a semiconductor device may include a semiconductor layer on a substrate, a first insulating layer on the semiconductor layer, a first conductive structure, which is provided to penetrate the first insulating layer in a vertical direction perpendicular to a bottom surface of the substrate and is connected to the semiconductor layer, a second insulating layer covering the first insulating layer and the first conductive structure, and a second conductive structure, which is provided to penetrate the second insulating layer in the vertical direction and is connected to the first conductive structure. The first insulating layer and the second insulating layer may include different materials from each other, and the lowermost surface of the second conductive structure may be spaced apart from a top surface of the first insulating layer.

According to an embodiment of the inventive concept, a semiconductor device may include a substrate including a cell region and a peripheral region, a semiconductor layer on the substrate, a first insulating layer on the semiconductor layer, a first conductive structure, which is provided to penetrate the first insulating layer in a vertical direction perpendicular to a bottom surface of the substrate and is connected to the semiconductor layer, a second insulating layer covering the first insulating layer and the first conductive structure, and a second conductive structure, which is provided to penetrate the second insulating layer in the vertical direction and is connected to the first conductive structure. The semiconductor layer may include an active pattern on the cell region, a word line crossing the active pattern, a bit line extending in a direction crossing the word line, a capacitor connected to the active pattern, a peripheral active pattern on the peripheral region, and a peripheral word line crossing the peripheral active pattern. The capacitor may include a bottom electrode, a top electrode on the bottom electrode, and a dielectric layer between the bottom and top electrodes. The first insulating layer and the second insulating layer may include different materials from each other, and the lowermost surface of the second conductive structure may be spaced apart from a top surface of the first insulating layer.

### BRIEF DESCRIPTION OF THE DRAWINGS

FIGS. 1 to 6 are sectional views, each of which illustrates a semiconductor device according to an embodiment of the inventive concept.

FIGS. 7 to 10 are sectional views illustrating a method of fabricating a semiconductor device, according to an embodiment of the inventive concept.

FIGS. 11 and 12 are sectional views illustrating a method of fabricating a semiconductor device, according to an embodiment of the inventive concept.

FIG. 13 is a sectional view illustrating a method of fabricating a semiconductor device, according to an embodiment of the inventive concept.

FIG. 14 is a block diagram illustrating a semiconductor device including a data storage pattern according to an embodiment of the inventive concept.

FIG. 15 is an enlarged plan view illustrating a portion (e.g., ‘P1’ of FIG. 14) of a semiconductor device including a data storage pattern according to an embodiment of the inventive concept.

FIG. 16 is a sectional view taken along a line A-A′ of FIG. 15 according to example embodiments.

FIG. 17 is an enlarged view corresponding to a portion ‘P2’ of FIG. 16 according to example embodiments.

FIG. 18 is a sectional view taken along the line A-A′ of FIG. 15 according to example embodiments.

FIG. 19 is an enlarged view corresponding to a portion ‘P3’ of FIG. 18 according to example embodiments.

### DETAILED DESCRIPTION

Example embodiments of the inventive concepts will now be described more fully with reference to the accompanying drawings, in which example embodiments are shown.

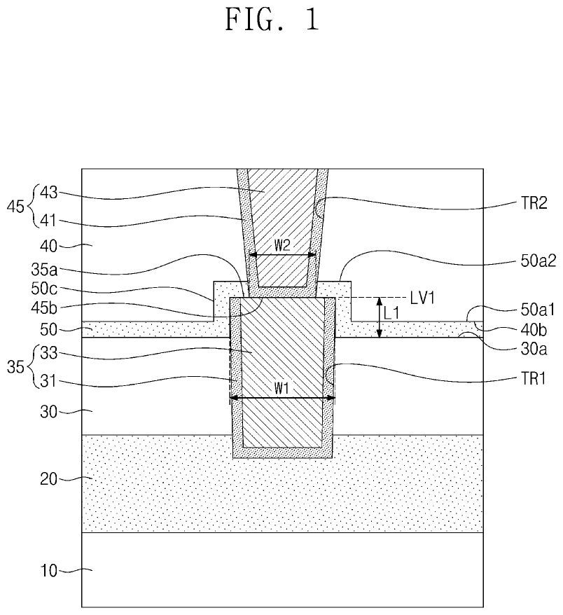

FIG. 1 is a sectional view illustrating a semiconductor device according to an embodiment of the inventive concept.

Referring to FIG. 1, a substrate 10 may be provided. The substrate 10 may be a semiconductor substrate (e.g., a silicon substrate, a germanium substrate, or a silicon-germanium substrate).

A semiconductor layer 20 may be provided on the substrate 10. The semiconductor layer 20 may include one of field effect transistors (FETs). As an example, the field effect transistor may be a metal-oxide-semiconductor FET (MOSFET), but the inventive concept is not limited to this example.

A first insulating layer 30 may be provided on the semiconductor layer 20. The first insulating layer 30 may cover the semiconductor layer 20. The first insulating layer 30 may include an insulating material. In an embodiment, the first insulating layer 30 may be formed of or include at least one of silicon oxide, silicon nitride, silicon oxynitride, tetraethyl orthosilicate (TEOS), or low-k dielectric materials. In the present specification, the low-k dielectric materials may refer to materials (e.g., SiCOH) whose dielectric constants are lower than silicon oxide. The first insulating layer 30 may be a single layer, which is made of one of the above materials, or a composite layer, which is made of at least two of the above materials. In an embodiment, the first insulating layer 30 may further contain a hydrogen ion.

A first conductive structure 35 may be provided to penetrate the first insulating layer 30. The first conductive structure 35 may be provided to penetrate the first insulating layer 30 in a direction perpendicular to a bottom surface of the substrate 10. The first conductive structure 35 may be connected to the semiconductor layer 20. In the present specification, the phrase “A is connected to B” may be used not only to indicate “A is in contact with B” but also to represent the meaning that “A is electrically connected to B through another element even if they are not in physical contact with each other”. The term “contact,” or “in contact with” as used herein refers to direct contact (i.e., touching) unless the context indicates otherwise. The phrase “the first conductive structure 35 is connected to the semiconductor layer 20” may mean that the first conductive structure 35 is connected to a field effect transistor of the semiconductor layer 20. As an example, the first conductive structure 35 may be connected to a source-drain electrode of the field effect transistor. As another example, the first conductive structure 35 may be connected to a gate electrode of the field effect transistor, but the inventive concept is not limited to this example.

A top surface 35a of the first conductive structure 35 may be located at a height that is higher than a top surface 30a of the first insulating layer 30. A height, at which the top surface 35a of the first conductive structure 35 is located, may be defined as a first level LV1. The top surface 30a of the first insulating layer 30 may be located at a height that is lower than the first level LV1. A length from the top surface 30a of the first insulating layer 30 to the first level LV1 may be defined as a first length L1. The first length L1 may be greater than 0 Å and less than or equal to 6000 Å.

The first conductive structure 35 may extend from an inner space of the first insulating layer 30 and protrude above the top surface 30a of the first insulating layer 30. As an example, a portion of a side surface of the first conductive structure 35 may be enclosed by the first insulating layer 30. As another example, a portion (e.g., an upper portion) of the side surface of the first conductive structure 35 may not be enclosed by the first insulating layer 30.

The first conductive structure 35 may include a first conductive barrier pattern 31 and a first conductive pattern 33. The first conductive pattern 33 may be provided to penetrate the first insulating layer 30. The first conductive barrier pattern 31 may be interposed between the first insulating layer 30 and the first conductive pattern 33. The first conductive structure 35 may be provided to fill a first trench TR1 in the first insulating layer 30. The first conductive barrier pattern 31 may conformally cover an inner surface of the first trench TR1. The first conductive pattern 33 may fill a remaining portion of the first trench TR1 covered with the first conductive barrier pattern 31.

Each of the first conductive barrier pattern 31 and the first conductive pattern 33 may be independently formed of or include at least one of metallic materials (e.g., Ti, Mo, W, Cu, Al, Ta, Ru, and Ir) or nitride materials containing the metallic material. In an embodiment, the first conductive barrier pattern 31 may be formed of or include at least one of metal nitride materials, and the first conductive pattern 33 may be formed of or include at least one of metallic materials.

A second insulating layer 40 may be provided on the first insulating layer 30. The second insulating layer 40 may cover the first insulating layer 30. The second insulating layer 40 may enclose a portion (e.g., an upper portion) of the side surface of the first conductive structure 35. A bottom surface 40b of the second insulating layer 40 may be located at a height lower than the first level LV1, but the inventive concept is not limited to this example. In an embodiment, the second insulating layer 40 may be formed of or include at least one of silicon oxide, silicon nitride, TEOS, or low-k dielectric materials. The second insulating layer 40 may be a single layer, which is made of one of the above materials, or a composite layer, which is made of at least two of the above materials. The second insulating layer 40 may include a material that is the same as or different from the first insulating layer 30. In an embodiment, the first insulating layer 30 may be formed of or include TEOS, and the second insulating layer 40 may be formed of or include at least one of low-k dielectric materials.

A diffusion barrier layer 50 may be interposed between the first and second insulating layers 30 and 40. The diffusion barrier layer 50 may conformally cover the top surface 30a of the first insulating layer 30. The diffusion barrier layer 50 may be in contact with the first insulating layer 30, at a height lower than the first level LV1. The diffusion barrier layer 50 may be extended from a region between the first and second insulating layers 30 and 40 to a region on the side surface of the first conductive structure 35. In an embodiment, the diffusion barrier layer 50 may be further extended to cover a portion of the top surface 35a of the first conductive structure 35. However, the inventive concept is not limited to this example. The diffusion barrier layer 50 may be interposed between the second insulating layer 40 and the first conductive structure 35.

The diffusion barrier layer 50 may have a first top surface 50a1 and a second top surface 50a2, which are located at different heights from each other. The first top surface 50al of the diffusion barrier layer 50 may be placed between the first and second insulating layers 30 and 40 and may be extended to be parallel to the bottom surface of the substrate 10. The second top surface 50a2 of the diffusion barrier layer 50 may be placed between the first conductive structure 35 and the second insulating layer 40. The second top surface 50a2 of the diffusion barrier layer 50 may be the uppermost surface of the diffusion barrier layer 50. The diffusion barrier layer 50 may have an outer side surface 50c, which is placed on the side surface of the first conductive structure 35. The first and second top surfaces 50al and 50a2 of the diffusion barrier layer 50 may be physically connected to each other by the outer side surface 50c of the diffusion barrier layer 50.

The first top surface 50al of the diffusion barrier layer 50 may be located at a height lower than the second top surface 50a2. The first top surface 50al of the diffusion barrier layer 50 may be located at a height lower than the first level LV1. The second top surface 50a2 of the diffusion barrier layer 50 may be located at the first level LV1 and at a height different from the first level LV1. In an embodiment, the second top surface 50a2 of the diffusion barrier layer 50 may be located at a height higher than the first level LV1.

The diffusion barrier layer 50 may be formed of or include at least one of nitride materials, which contain a metallic element (e.g., Ti, Mo, W, Cu, Al, Ta, Ru, or Ir), or silicon oxynitride. The diffusion barrier layer 50 may be a single layer, which is made of one of the above materials, or a composite layer, which is made of at least two of the above materials. As an example, the diffusion barrier layer 50 may be a composite layer that includes AlN and silicon oxynitride.

A second conductive structure 45 may be provided to penetrate the second insulating layer 40. The second conductive structure 45 may be provided to penetrate the second insulating layer 40 in a direction perpendicular to the bottom surface of the substrate 10. The second conductive structure 45 may be connected to the first conductive structure 35. In an embodiment, the second conductive structure 45 may be connected to the semiconductor layer 20 through the first conductive structure 35.

The second conductive structure 45 may have a bottom surface 45b. At least a portion of the bottom surface 45b of the second conductive structure 45 may be located at the first level LV1. As an example, the second conductive structure 45 may have the lowermost surface at the first level LV1, but the inventive concept is not limited to this example. The bottom surface 45b of the second conductive structure 45 may be located at a height higher than the top surface 30a of the first insulating layer 30. The bottom surface 45b of the second conductive structure 45 may be located at a height higher than the first top surface 50al of the diffusion barrier layer 50. The bottom surface 45b of the second conductive structure 45 may be located at a height that is the same as or different from the second top surface 50a2 of the diffusion barrier layer 50. As an example, the bottom surface 45b of the second conductive structure 45 may be located at a height lower than the second top surface 50a2 of the diffusion barrier layer 50. The bottom surface 45b of the second conductive structure 45 may be spaced apart from the top surface 30a of the first insulating layer 30.

The bottom surface 45b of the second conductive structure 45 may be in contact with the first conductive structure 35 at the first level LV1. At the first level LV1, the first conductive structure 35 may have a first width W1, and the second conductive structure 45 may have a second width W2. The second width W2 may be equal to or different from the first width W1. In an embodiment, the second width W2 may be smaller than the first width W1. A side surface of the second conductive structure 45 may be enclosed by the second insulating layer 40. At least a portion of the top surface 35a of the first conductive structure 35 may be covered with the second conductive structure 45. In an embodiment, the side surface of the second conductive structure 45 may be enclosed by the second insulating layer 40 and the diffusion barrier layer 50.

The second conductive structure 45 may include a second conductive barrier pattern 41 and a second conductive pattern 43. The second conductive pattern 43 may be provided to penetrate the second insulating layer 40. The second conductive barrier pattern 41 may be interposed between the second insulating layer 40 and the second conductive pattern 43. The second conductive structure 45 may be provided to fill a second trench TR2 in the second insulating layer 40. The second conductive barrier pattern 41 may conformally cover an inner surface of the second trench TR2. The second conductive pattern 43 may be provided to fill a remaining portion of the second trench TR2 covered with the second conductive barrier pattern 41.

Each of the second conductive barrier pattern 41 and the second conductive pattern 43 may be independently formed of or include at least one of metallic materials (e.g., Ti, Mo, W, Cu, Al, Ta, Ru, and Ir) or nitride materials containing the metallic material. In an embodiment, the second conductive barrier pattern 41 may be formed of or include at least one of metal nitride materials, and the second conductive pattern 43 may be formed of or include at least one of metallic materials. The second conductive pattern 43 may be formed of or include a material that is the same as or different from the first conductive pattern 33. In an embodiment, the first and second conductive patterns 33 and 43 may be formed of or include tungsten (W) and copper (Cu), respectively, but the inventive concept is not limited to this example.

According to an embodiment of the inventive concept, the first and second conductive structures 35 and 45 may be in contact with each other at the first level LV1. The top surface 30a of the first insulating layer 30 may be provided at a height lower than the first level LV1. Thus, it may be possible to prevent an interface defect, which may occur at an interface between the first and second conductive structures 35 and 45, from spreading along a top surface of the first insulating layer 30. As a result, the reliability characteristics of the semiconductor device may be improved. In addition, since the bottom surface 45b of the second conductive structure 45 is spaced apart from the top surface 30a of the first insulating layer 30, it may be possible to prevent hydrogen ions in the first insulating layer 30 from being diffused into the second conductive structure 45. Accordingly, it may be possible to prevent the second conductive structure 45 from being deteriorated and thereby to improve the electrical and reliability characteristics of the semiconductor device.

According to an embodiment of the inventive concept, since the top surface 30a of the first insulating layer 30 is placed below the first level LV1, a volume of the second insulating layer 40 may be increased. Here, in the case where the second insulating layer 40 includes a low-k dielectric material, it may be possible to reduce a capacitance of an insulating layer enclosing the conductive structures. As a result, the electric characteristics of the semiconductor device may be improved.

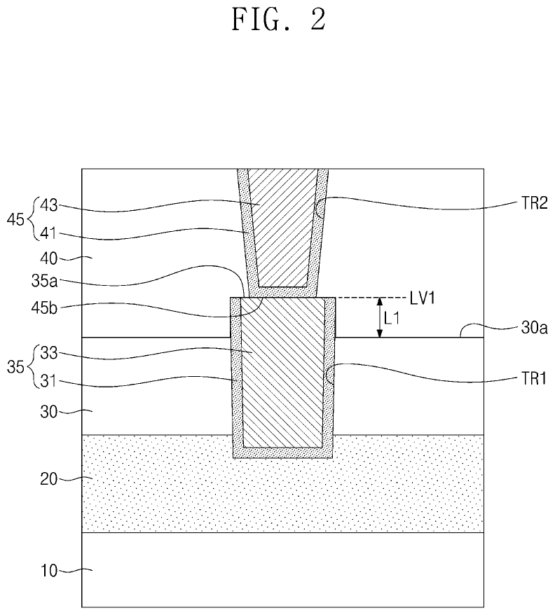

FIG. 2 is a sectional view illustrating a semiconductor device according to an embodiment of the inventive concept. For concise description, a previously described element may be identified by the same reference number without repeating an overlapping description thereof.

Referring to FIG. 2, the first and second insulating layers 30 and 40 may be in contact with each other. The top surface 30a of the first insulating layer 30 may be in contact with the bottom surface 40b of the second insulating layer 40. The top surface 30a of the first insulating layer 30 and the bottom surface 40b of the second insulating layer 40 may be located at a height lower than the first level LV1. The bottom surface 45b of the second conductive structure 45 may be spaced apart from the top surface 30a of the first insulating layer 30.

The diffusion barrier layer 50 of FIG. 1 may be omitted from the semiconductor device in the present embodiment. In an embodiment, the diffusion barrier layer 50 of FIG. 1 may be locally provided, and in this case, the first and second insulating layers 30 and 40 may be in contact with each other in a region where the diffusion barrier layer 50 is not provided.

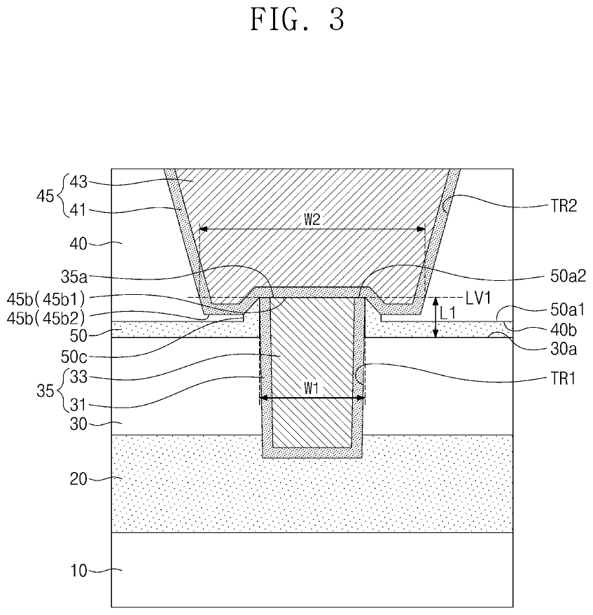

FIGS. 3 to 5 are sectional views, each of which illustrates a semiconductor device according to an embodiment of the inventive concept. For concise description, a previously described element may be identified by the same reference number without repeating an overlapping description thereof.

Referring to FIGS. 3 to 5, the second width W2 of the second conductive structure 45 may be larger than the first width W1 of the first conductive structure 35. In an embodiment, the top surface 35a of the first conductive structure 35 may be completely covered with the second conductive structure 45.

The second conductive structure 45 may have a first bottom surface 45b1 and a second bottom surface 45b2, which are located at different heights. The first bottom surface 45b1 of the second conductive structure 45 may be in contact with the top surface 35a of the first conductive structure 35. The first bottom surface 45b1 of the second conductive structure 45 may be located at the first level LV1. The second bottom surface 45b2 of the second conductive structure 45 may be located at a height lower than the first level LV1. The second bottom surface 45b2 of the second conductive structure 45 may not cover a top surface of the first conductive structure 35. For example, the second bottom surface 45b2 of the second conductive structure 45 may be in contact with the second insulating layer 40.

The second bottom surface 45b2 of the second conductive structure 45 may be located at a height lower than the first bottom surface 45b1. As an example, the second bottom surface 45b2 of the second conductive structure 45 may be the lowermost surface of the second conductive structure 45. The second bottom surface 45b2 of the second conductive structure 45 may be located at a height higher than the top surface 30a of the first insulating layer 30. The second bottom surface 45b2 of the second conductive structure 45 may be spaced apart from the top surface 30a of the first insulating layer 30. As an example, the second bottom surface 45b2 of the second conductive structure 45 may be located at a height higher than the first top surface 50al of the diffusion barrier layer 50. The second bottom surface 45b2 of the second conductive structure 45 may be spaced apart from the first top surface 50al of the diffusion barrier layer 50.

Referring to FIG. 3, the second top surface 50a2 of the diffusion barrier layer 50 may be located at a height, which is the same as or lower than the first level LV1. Thus, the diffusion barrier layer 50 may be located at a height, which is the same as or lower than the first level LV1. The diffusion barrier layer 50 on the side surface of the first conductive structure 35 may have a thickness that varies depending on its height. As an example, the thickness of the diffusion barrier layer 50 on the side surface of the first conductive structure 35 may decrease in an upward direction, but the inventive concept is not limited to this example.

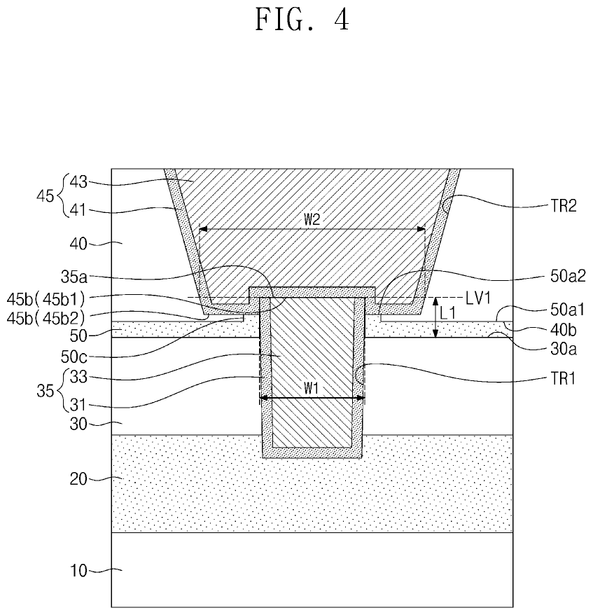

Referring to FIG. 4, the second top surface 50a2 of the diffusion barrier layer 50 may be located at a height, which is the same as or lower than the first level LV1. Thus, the diffusion barrier layer 50 may be located at a height, which is the same as or lower than the first level LV1. The second top surface 50a2 of the diffusion barrier layer 50 on the side surface of the first conductive structure 35 may have a thickness that is substantially constant regardless of its height. The second top surface 50a2 of the diffusion barrier layer 50 may be parallel to the bottom surface of the substrate 10. The second top surface 50a2 of the diffusion barrier layer 50 may serve as a part of an inner bottom surface of the second trench TR2. As an example, the second top surface 50a2 of the diffusion barrier layer 50 may be located at substantially the same height as an inner surface of the second insulating layer 40 adjacent thereto and may be coplanar with the inner surface of the second insulating layer 40.

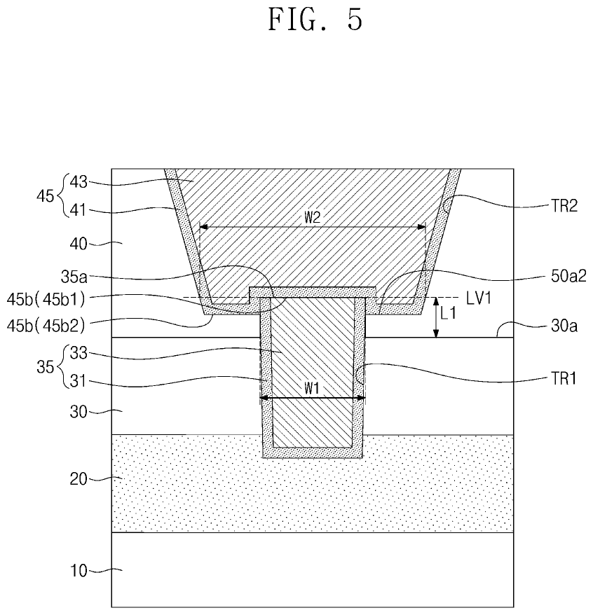

Referring to FIG. 5, the first and second insulating layers 30 and 40 may be in contact with each other. The top surface 30a of the first insulating layer 30 may be in contact with the bottom surface 40b of the second insulating layer 40. The second bottom surface 45b2 of the second conductive structure 45 may be spaced apart from the top surface 30a of the first insulating layer 30.

The diffusion barrier layer 50 of FIG. 3 or 4 may be omitted from the semiconductor device in the present embodiment. In an embodiment, the diffusion barrier layer 50 may be locally provided, and in this case, the first and second insulating layers 30 and 40 may be in contact with each other in a region where the diffusion barrier layer 50 is not provided.

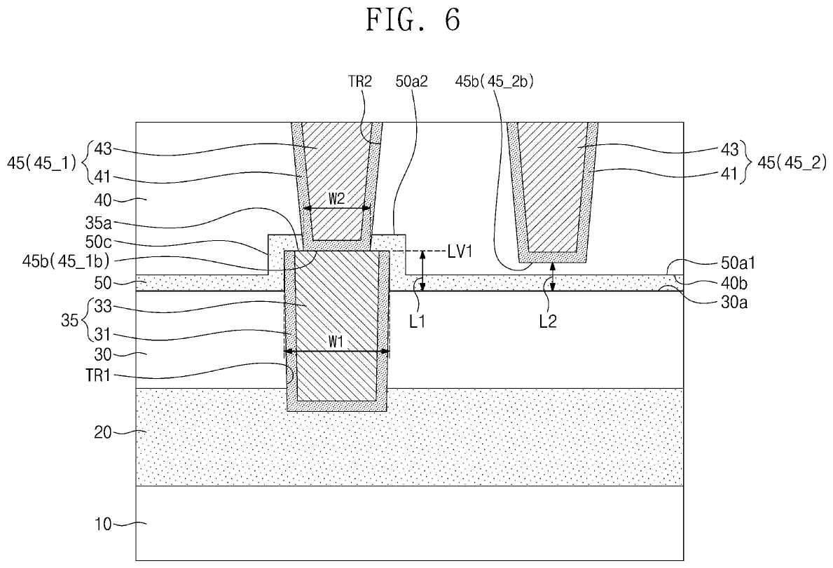

FIG. 6 is a sectional view illustrating a semiconductor device according to an embodiment of the inventive concept. For concise description, a previously described element may be identified by the same reference number without repeating an overlapping description thereof.

Referring to FIG. 6, the second conductive structure 45 may include a plurality of structures. As an example, the second conductive structure 45 may include a first structure 45_1 and a second structure 45_2. The first structure 45_1 may correspond to the second conductive structure 45 described with reference to FIGS. 1 to 5. The second structure 45_2 may not be in contact with the first conductive structure 35 and may not be connected to the first conductive structure 35.

In an embodiment, a bottom surface 45_2b of the second structure 45_2 may be in contact with the second insulating layer 40. The bottom surface 45_2b of the second structure 45_2 may be located at a height that is higher than the top surface 30a of the first insulating layer 30 and is lower than the first level LV1. The bottom surface 45_2b of the second structure 45_2 may be spaced apart from the top surface 30a of the first insulating layer 30. A length from the top surface 30a of the first insulating layer 30 to the bottom surface 45_2b of the second structure 45_2 may be defined as a second length L2. In an embodiment, the second length L2 may be shorter than the first length L1. The bottom surface 45_2b of the second structure 45_2 may be located at a height higher than the first top surface 50al of the diffusion barrier layer 50.

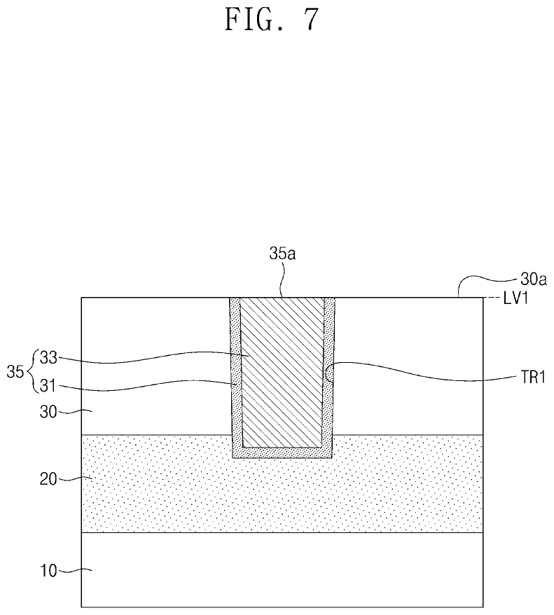

FIGS. 7 to 10 are sectional views illustrating a method of fabricating a semiconductor device, according to an embodiment of the inventive concept. For concise description, a previously described element may be identified by the same reference number without repeating an overlapping description thereof.

Referring to FIG. 7, the substrate 10 may be provided. The semiconductor layer 20 may be formed on the substrate 10. In an embodiment, the formation of the semiconductor layer 20 may include forming field effect transistors using, for example, a conventional MOSFET process. The first insulating layer 30 may be formed on the semiconductor layer 20. The first insulating layer 30 may be formed using at least one of a physical vapor deposition method, a chemical vapor deposition method, or an atomic layer deposition method.

Thereafter, the first trench TR1 may be formed to penetrate the first insulating layer 30. The formation of the first trench TR1 may include forming mask patterns (not shown) on the first insulating layer 30 and performing an etching process on the first insulating layer 30 using the mask patterns as an etch mask.

The first conductive structure 35 may be formed in the first trench TR1. In an embodiment, the formation of the first conductive structure 35 may include forming the first conductive barrier pattern 31 to conformally cover an inner surface of the first trench TR1, forming a first conductive layer (not shown) to fill the first trench TR1 and cover the top surface 30a of the first insulating layer 30, and removing an upper portion of the first conductive layer to form a plurality of first conductive patterns 33 separated from each other. In an embodiment, the removing of the upper portion of the first conductive layer may include performing a chemical mechanical polishing (CMP) process on the first conductive layer. After the formation of the first conductive structure 35, a deposition process may be further performed to form the first insulating layer 30 covering the top surface of the first conductive structure 35. However, the inventive concept is not limited to this example.

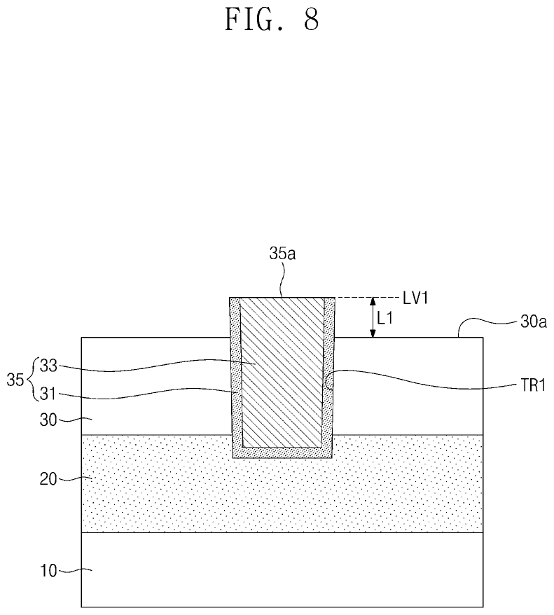

Referring to FIG. 8, an upper portion of the first insulating layer 30 may be removed. For example, the upper portion of the first insulating layer 30 may be vertically recessed. In an embodiment, the removal of the upper portion of the first insulating layer 30 may include performing a wet etching process or an etch-back process on the upper portion of the first insulating layer 30.

As a result of the removal process, an upper portion of the first conductive structure 35 may be exposed to the outside. For example, a portion (e.g., an upper portion) of the side surface of the first conductive structure 35 may not be covered with the first insulating layer 30. The top surface 35a of the first conductive structure 35 may be formed at the first level LV1. The top surface 30a of the first insulating layer 30 may be formed at a height that is lower by the first length L1 than the top surface 35a of the first conductive structure 35.

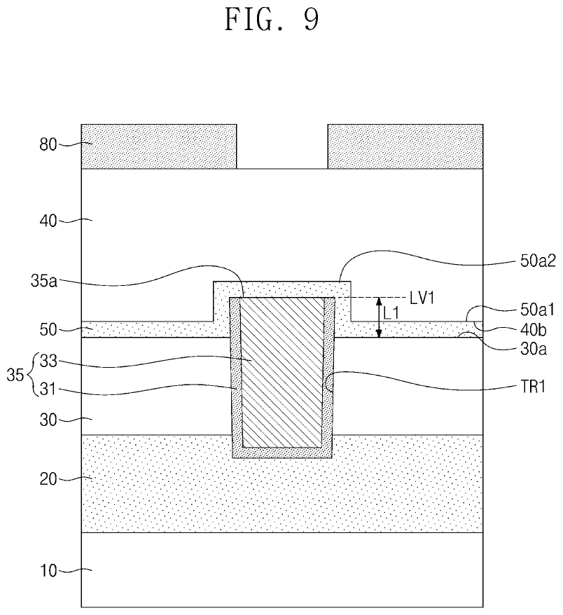

Referring to FIG. 9, the diffusion barrier layer 50 may be formed on the first insulating layer 30. As an example, the diffusion barrier layer 50 may conformally cover the exposed upper portion of the first conductive structure 35 and the top surface of the first insulating layer 30. In an embodiment, the diffusion barrier layer 50 may be formed using at least one of a physical vapor deposition method, a chemical vapor deposition method, or an atomic layer deposition method.

The second insulating layer 40 may be formed on the first insulating layer 30. In an embodiment, the second insulating layer 40 may be formed to cover the diffusion barrier layer 50 on the first insulating layer 30. The formation of the second insulating layer 40 may include depositing the second insulating layer 40 on the first insulating layer 30 and performing a CMP process on an upper portion of the second insulating layer 40. As a result of the CMP process, the second insulating layer 40 may have a flat top surface. Thereafter, mask patterns 80 may be formed on the second insulating layer 40. The mask patterns 80 may include openings. At least one of the openings may be vertically overlapped with the first conductive structure 35.

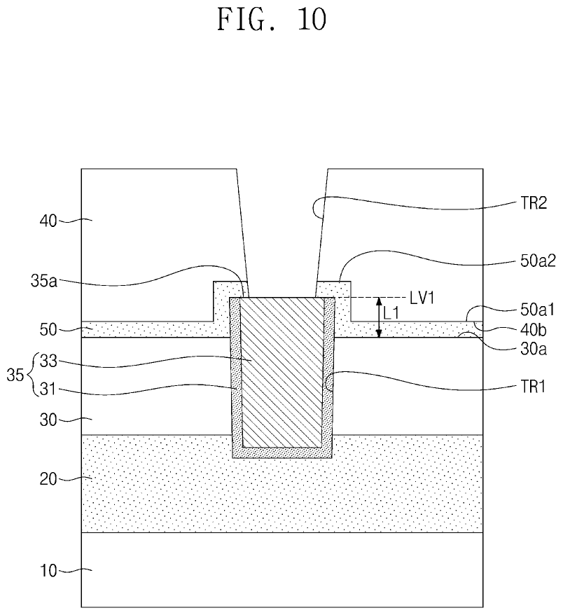

Referring to FIG. 10, a patterning process may be performed on the second insulating layer 40. The patterning process may include etching the second insulating layer 40 using the mask patterns 80 as an etch mask. As a result of the patterning process, the second trench TR2 may be formed in the second insulating layer 40. The second trench TR2 may be formed to expose the top surface 35a of the first conductive structure 35. As an example, the patterning process may be performed to further etch the diffusion barrier layer 50.

Referring back to FIG. 1, the second conductive structure 45 may be formed in the second trench TR2. The formation of the second conductive structure 45 may include forming the second conductive barrier pattern 41 to conformally cover an inner surface of the second trench TR2, forming a second conductive layer (not shown) to fill the second trench TR2 and cover the top surface of the second insulating layer 40, and removing an upper portion of the second conductive layer to form a plurality of second conductive patterns 43 separated from each other. In an embodiment, the formation of the second conductive layer may include forming a seed conductive layer (not shown) and forming the second conductive layer by an electroplating process, in which the seed conductive layer is used as a seed layer. In an embodiment, the removing of the upper portion of the second conductive layer may include performing a CMP process on the second conductive layer. Thereafter, to form an interconnection structure of the semiconductor device, an additional routing process may be further performed using a conventional method, although not shown.

In an embodiment, the process of forming the diffusion barrier layer 50 described with reference to FIG. 9 may be omitted. Alternatively, the diffusion barrier layer 50 may be formed in only a localized region. In this case, the semiconductor device may have the structure of FIG. 2.

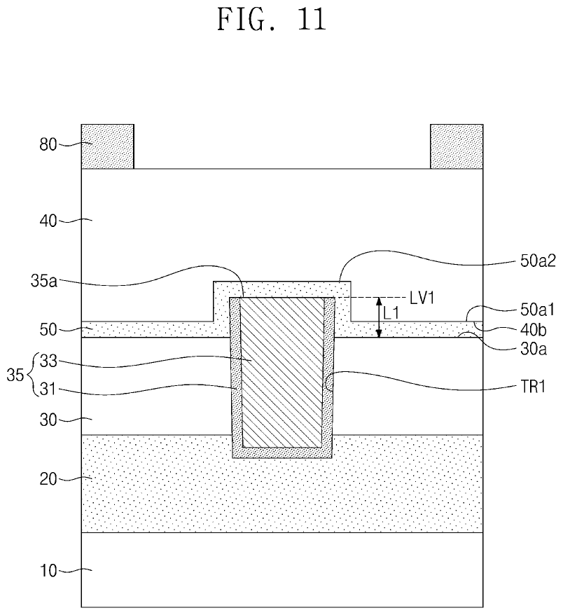

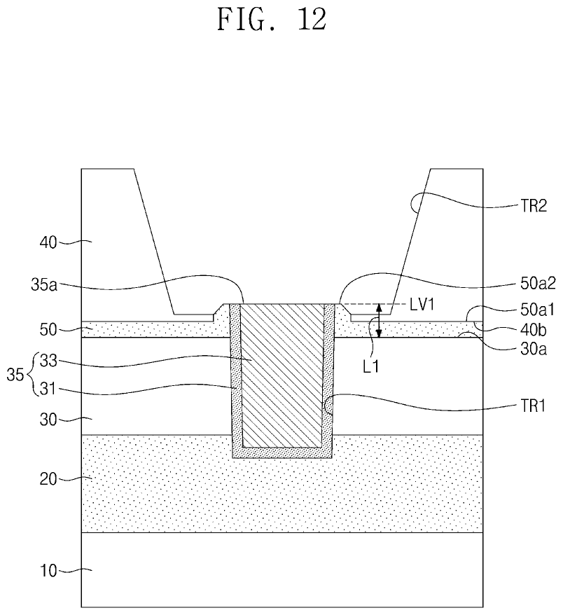

FIGS. 11 and 12 are sectional views illustrating a method of fabricating a semiconductor device, according to an embodiment of the inventive concept. For concise description, a previously described element may be identified by the same reference number without repeating an overlapping description thereof.

Referring to FIG. 11, after the formation of the second insulating layer 40, the mask patterns 80 may be formed on the second insulating layer 40. The mask patterns 80 may include openings. At least one of the openings may be formed to have a width that is larger than a width of a corresponding one of the first conductive structures 35.

Referring to FIG. 12, a patterning process may be performed on the second insulating layer 40. As a result of the patterning process, the second trench TR2 may be formed in the second insulating layer 40. An inner bottom surface of the second trench TR2 may be defined by the top surface of the first conductive structure 35 and the second insulating layer 40. A portion of the inner bottom surface of the second trench TR2 defined by the second insulating layer 40 may be formed at a height that is lower than another portion of the inner bottom surface of the second trench TR2 defined by the first conductive structure 35. The inner bottom surface of the second trench TR2 may be formed at a height that is higher than the top surface 30a of the first insulating layer 30.

In the case where the diffusion barrier layer 50 is provided, a portion of the diffusion barrier layer 50 may also be etched when the second insulating layer 40 is etched. Here, a profile of the diffusion barrier layer 50 near the first conductive structure 35 may depend on a process condition for the process of etching the diffusion barrier layer 50. As an example, the diffusion barrier layer 50 on the side surface of the first conductive structure 35 may be formed to have a thickness that varies depending on its height. The second top surface 50a2 of the diffusion barrier layer 50 may be formed at the first level LV1.

A subsequent process of forming the second conductive structure 45 may be performed using the afore-described method, and in this case, the semiconductor device may be formed to have the structure of FIG. 3.

In an embodiment, the process of forming the diffusion barrier layer 50 may be omitted. Alternatively, the diffusion barrier layer 50 may be formed in only a localized region. In this case, the semiconductor device may have the structure of FIG. 5.

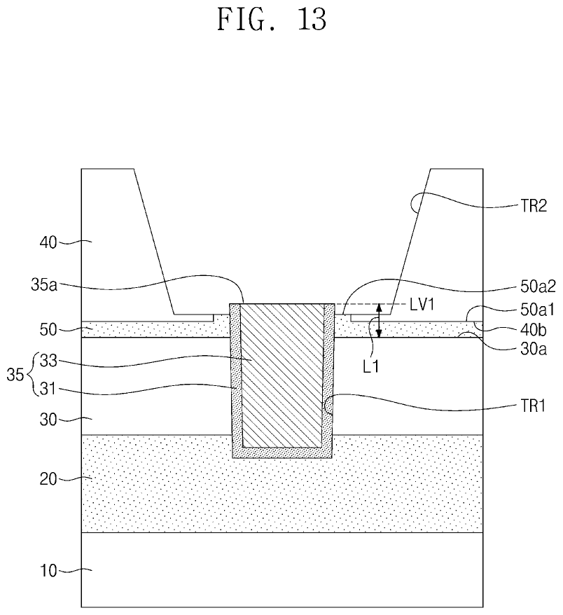

FIG. 13 is a sectional view illustrating a method of fabricating a semiconductor device, according to an embodiment of the inventive concept. For concise description, a previously described element may be identified by the same reference number without repeating an overlapping description thereof.

Referring to FIG. 13, in the process of etching the second insulating layer 40, a portion of the diffusion barrier layer 50 may also be etched. Here, the second top surface 50a2 of the diffusion barrier layer 50 may be formed at a height lower than the first level LV1. The second top surface 50a2 of the diffusion barrier layer 50 may be formed at the same height as an inner bottom surface of the second trench TR2 defined by the second insulating layer 40. In an embodiment, the second top surface 50a2 of the diffusion barrier layer 50 may be formed to be parallel to the substrate 10.

A subsequent process of forming the second conductive structure 45 may be performed using the afore-described method, and in this case, the semiconductor device may be formed to have the structure of FIG. 4.

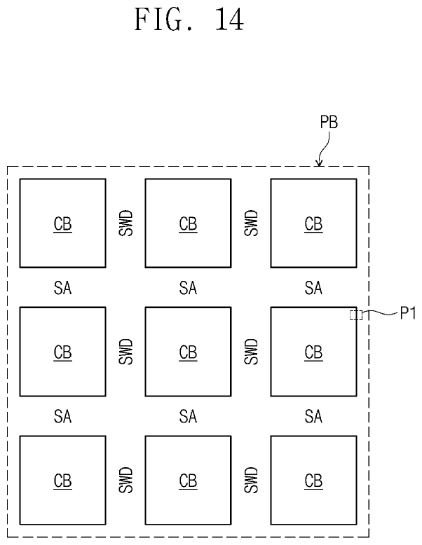

FIG. 14 is a block diagram illustrating a semiconductor device including a data storage pattern according to an embodiment of the inventive concept.

Referring to FIG. 14, a semiconductor device may include cell blocks CB and a peripheral block PB, which is provided to surround each of the cell blocks CB. Each of the cell blocks CB may include a cell circuit, such as a memory cell array. The peripheral block PB may include various peripheral circuits, which are used to operate the cell circuit, and the peripheral circuits may be electrically connected to the cell circuit.

The peripheral block PB may include sense amplifier circuits SA and sub-word line driver circuits SWD. In an embodiment, the sense amplifier circuits SA may be provided to face each other with the cell blocks CB interposed therebetween, and the sub-word line driver circuits SWD may be provided to face each other with the cell blocks CB interposed therebetween. The peripheral block PB may further include power and ground circuits for, operating the sense amplifier circuits SA and sub-word line driver, but the inventive concept is not limited to this example.

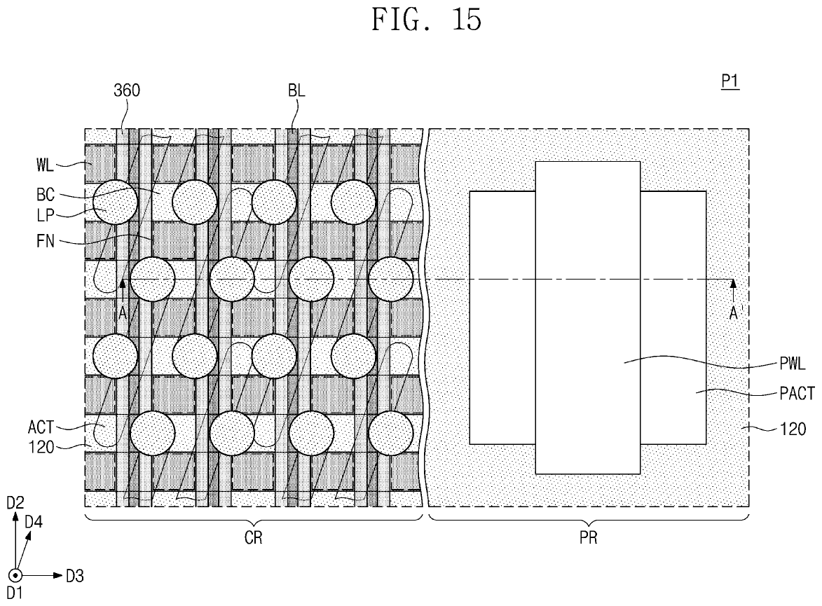

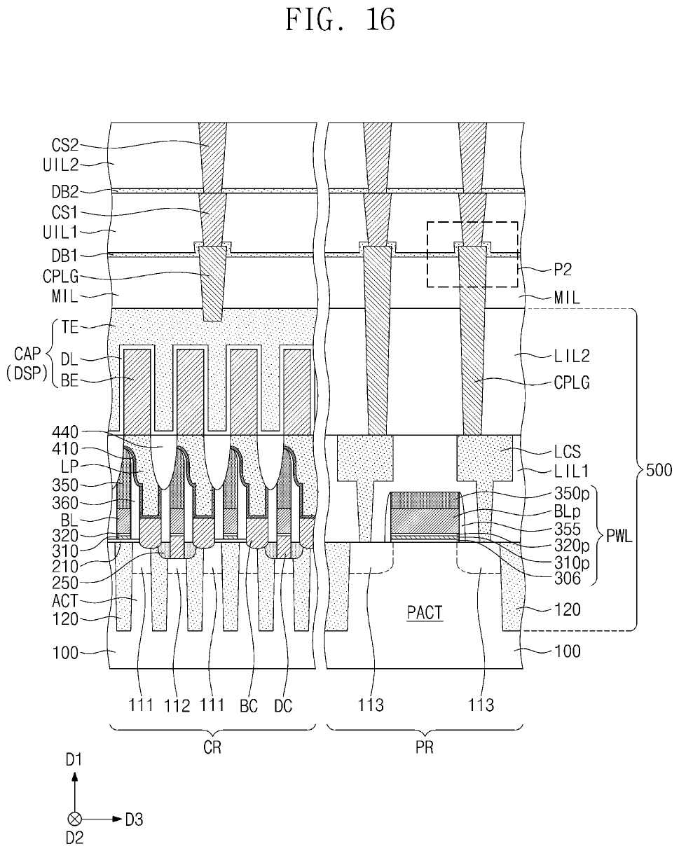

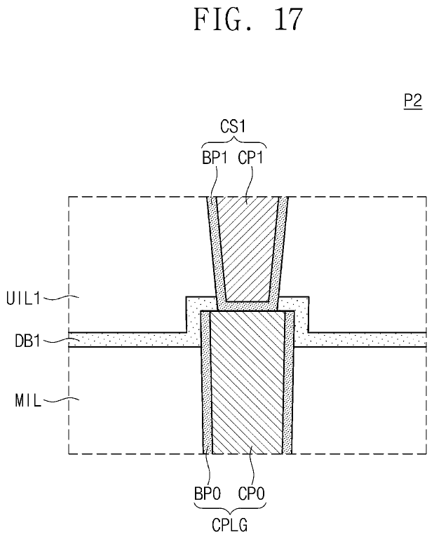

FIG. 15 is an enlarged plan view illustrating a portion (e.g., ‘P1’ of FIG. 14) of a semiconductor device including a data storage pattern according to an embodiment of the inventive concept. FIG. 16 is a sectional view taken along a line A-A′ of FIG. 15. FIG. 17 is an enlarged view corresponding to a portion ‘P2’ of FIG. 16 according to example embodiments. For concise description, a previously described element may be identified by the same reference number without repeating an overlapping description thereof.

Referring to FIGS. 15 to 17, a substrate 100 may be provided. The substrate 100 may correspond to the substrate 10 described with reference to FIG. 1. In an embodiment, the substrate 100 may include a cell region CR and a peripheral region PR. The cell region CR may be a region of the substrate 10, on which the cell blocks CB of FIG. 14 are provided. The peripheral region PR may be another region of the substrate 10, on which the peripheral block PB of FIG. 14 is provided.

A device isolation pattern 120 may be disposed on the substrate 100. The device isolation pattern 120 may define active patterns ACT in the cell region CR of the substrate 100. The device isolation pattern 120 may define peripheral active patterns PACT in the peripheral region PR of the substrate 100. Each of the active patterns ACT and the peripheral active patterns PACT may have a protruding shape in a first direction D1 perpendicular to a bottom surface of the substrate 100. In an embodiment, the device isolation pattern 120 may be disposed in the substrate 100, and the active patterns ACT and the peripheral active patterns PACT may be portions of the substrate 100 enclosed by the device isolation pattern 120. In the present specification, for convenience of explanation, the substrate 100 may be defined to represent the remaining portion of the substrate 100, except for the active patterns ACT and the peripheral active patterns PACT, unless otherwise specified.

The active patterns ACT may be spaced apart from each other in a second direction D2 and a third direction D3, which are non-parallel (e.g., orthogonal) to each other. Each of the second and third directions D2 and D3 may be parallel to the bottom surface of the substrate 100. The active patterns ACT may be isolated bar-shaped patterns, which are spaced apart from each other and are elongated in a fourth direction D4. The fourth direction D4 may be parallel to the bottom surface of the substrate 100 and may not be parallel to the second and third directions D2 and D3.

The device isolation pattern 120 may include an insulating material. In an embodiment, the device isolation pattern 120 may be formed of or include at least one of silicon oxide or silicon nitride. The device isolation pattern 120 may be a single layer, which is made of one of the above materials, or a composite layer, which is made of at least two of the above materials.

First impurity regions 111 and second impurity regions 112 may be provided in the active patterns ACT. In an embodiment, a pair of first impurity regions 111 may be provided in opposite edge regions of each active pattern ACT. Each second impurity region 112 may be interposed between the pair of the first impurity regions 111. The first and second impurity regions 111 and 112 may contain impurities of the same conductivity type (e.g., n-type).

Third impurity regions 113 may be provided in the peripheral active patterns PACT. In an embodiment, a pair of third impurity regions 113 may be provided in opposite edge regions of each peripheral active pattern PACT. The third impurity regions 113 may include n- or p-type impurities.

A word line WL may be disposed to cross the active patterns ACT. As an example, the word line WL may cross the active patterns ACT and the device isolation pattern 120 in the third direction D3. In an embodiment, a plurality of word lines WL may be provided. The word lines WL may be spaced apart from each other in the second direction D2. As an example, a pair of word lines WL, which are adjacent to each other in the second direction D2, may be provided to cross each of the active patterns ACT.

As an example, each of the word lines WL may include a gate electrode (not shown), a gate insulating pattern (not shown), and a gate capping pattern (not shown). The gate electrode may be provided to cross the active patterns ACT and the device isolation pattern 120 in the third direction D3. The gate insulating pattern may be interposed between the gate electrode and the active patterns ACT. The gate capping pattern may cover a top surface of the gate electrode.

A buffer pattern 210 may be disposed on the substrate 100. The buffer pattern 210 may cover the active patterns ACT, the device isolation pattern 120, and the word lines WL. In an embodiment, the buffer pattern 210 may be formed of or include at least one of silicon oxide, silicon nitride, silicon oxynitride, or combinations thereof. The buffer pattern 210 may be a single layer, which is made of a single material, or a composite layer including two or more materials.

A bit line contact DC may be provided on each of the active patterns ACT, and in an embodiment, a plurality of bit line contacts DC may be provided. The bit line contacts DC may be connected to the second impurity regions 112 of the active patterns ACT, respectively. The bit line contacts DC may be spaced apart from each other in the second and third directions D2 and D3. The bit line contact DC may be interposed between each of the active patterns ACT and a corresponding one of bit lines BL, which will be described below. The bit line contacts DC may connect the bit lines BL to the second impurity regions 112 of the active patterns ACT, respectively.

The bit line contacts DC may be disposed in recess regions, respectively, and gapfill insulating patterns 250 may fill inner spaces of the recess regions. The gapfill insulating pattern 250 may be formed of or include at least one of silicon oxide or silicon nitride. The gapfill insulating pattern 250 may be a single layer, which is made of a single material, or a composite layer including two or more materials.

The bit line BL may be provided on the bit line contact DC. The bit line BL may be disposed on the bit line contacts DC, which are arranged in the second direction D2 to form a line. In an embodiment, a plurality of bit lines BL may be provided. The bit lines BL may be spaced apart from each other in the third direction D3. The bit line BL may be formed of or include at least one of metallic materials. As an example, the bit line BL may be formed of or include at least one of tungsten, rubidium, molybdenum, titanium, or combinations thereof.

A polysilicon pattern 310 may be interposed between the bit line BL and the buffer pattern 210. In an embodiment, a plurality of polysilicon patterns 310 may be provided. As an example, the polysilicon patterns 310 may be spaced apart from each other in the first and second directions D1 and D2. A top surface of the polysilicon pattern 310 may be located at substantially the same height as a top surface of the bit line contact DC. The polysilicon pattern 310 may be formed of or include doped polysilicon.

A first ohmic pattern 320 may be interposed between the bit line BL and the bit line contact DC and between the bit line BL and the polysilicon pattern 310. The first ohmic pattern 320 may be extended along the bit line BL and in the second direction D2. In an embodiment, a plurality of first ohmic patterns 320 may be provided. The first ohmic patterns 320 may be spaced apart from each other in the third direction D3. The first ohmic pattern 320 may be formed of or include a metal silicide material. A first barrier pattern (not shown) may be further interposed between the bit line BL and the bit line contact DC and between the bit line BL and the polysilicon pattern 310. The first barrier pattern may be formed of or include at least one of conductive metal nitride materials (e.g., titanium nitride and tantalum nitride).

A bit line capping pattern 350 may be provided on a top surface of the bit line BL. On the top surface of the bit line BL, the bit line capping pattern 350 may be extended in the second direction D2. In an embodiment, a plurality of bit line capping patterns 350 may be provided. The bit line capping patterns 350 may be spaced apart from each other in the third direction D3. The bit line capping pattern 350 may be vertically overlapped with the bit line BL. Each of the bit line capping patterns 350 may be composed of a single layer or a plurality of layers. In an embodiment, each of the bit line capping patterns 350 may include three or more capping patterns, which are sequentially stacked in the first direction D1.

A bit line spacer 360 may be provided on a side surface of the bit line BL and a side surface of the bit line capping pattern 350. The bit line spacer 360 may cover the side surface of the bit line BL and the side surface of the bit line capping pattern 350. The bit line spacer 360 on the side surface of the bit line BL may be extended in the second direction D2. In an embodiment, a plurality of bit line spacers 360 may be provided. The bit line spacers 360 may be spaced apart from each other in the first direction D1.

Each of the bit line spacers 360 may include a plurality of spacers. In an embodiment, each of the bit line spacers 360 may include three or more spacers, which are sequentially disposed on the side surface of the bit line BL in the third direction D3. As an example, each of the spacers may be independently formed of or include at least one of silicon nitride, silicon oxide, silicon oxynitride, or combinations thereof. As another example, at least one of the spacers may include an air gap separating others of the spacers from each other.

A storage node contact BC may be provided between adjacent ones of the bit lines BL. As an example, the storage node contact BC may be interposed between adjacent ones of the bit line spacers 360. In an embodiment, a plurality of storage node contacts BC may be provided. The storage node contacts BC may be spaced apart from each other in the second and third directions D2 and D3. The storage node contacts BC may be spaced apart from each other in the second direction D2 by fence patterns FN, which will be described below. The storage node contact BC may fill a recess region that is provided on the first impurity region 111 of the active pattern ACT. The storage node contact BC may be connected to the first impurity region 111. In an embodiment, the storage node contact BC may be formed of or include at least one of doped or undoped polysilicon or metallic materials.

The fence pattern FN may be provided between adjacent ones of the bit lines BL. In an embodiment, a plurality of fence patterns FN may be provided. The fence patterns FN may be spaced apart from each other in the second and third directions D2 and D3. The fence patterns FN, which are adjacent to each other in the third direction D3, may be spaced apart from each other with the bit line BL interposed therebetween. The fence patterns FN, which are adjacent to each other in the second direction D2, may be spaced apart from each other with the storage node contact BC interposed therebetween. In an embodiment, the fence patterns FN may be formed of or include silicon nitride.

A second barrier pattern 410 may conformally cover the bit line spacer 360, the fence pattern FN, and the storage node contact BC. The second barrier pattern 410 may be formed of or include at least one of metal nitride materials (e.g., titanium nitride and tantalum nitride). A second ohmic pattern (not shown) may be further interposed between the second barrier pattern 410 and the storage node contact BC. The second ohmic pattern may be formed of or include a metal silicide material.

A landing pad LP may be provided on the storage node contact BC. In an embodiment, a plurality of landing pads LP may be provided. The landing pads LP may be spaced apart from each other in the second and third directions D2 and D3. Each of the landing pads LP may be connected to a corresponding one of the storage node contacts BC. The landing pad LP may cover atop surface of the bit line capping pattern 350. A lower region of the landing pad LP may be vertically overlapped with the storage node contact BC. An upper region of the landing pad LP may be shifted from the lower region in the third direction D3. The landing pad LP may be formed of or include at least one of metallic materials (e.g., tungsten, titanium, and tantalum).

A filler pattern 440 may be provided to enclose the landing pad LP. The filler pattern 440 may be interposed between adjacent ones of the landing pads LP. When viewed in a plan view, the filler pattern 440 may be provided in the shape of a mesh with holes, and in this case, the landing pads LP may be provided in the holes to penetrate the filler pattern 440. The filler pattern 440 may be formed of or include at least one of silicon nitride, silicon oxide, silicon oxynitride, or combinations thereof. Alternatively, the filler pattern 440 may include an empty space with an air layer (i.e., an air gap).

A data storage pattern DSP may be provided on the landing pad LP. In an embodiment, a plurality of data storage patterns DSP may be provided. The data storage patterns DSP may be spaced apart from each other in the second and third directions D2 and D3. Each of the data storage patterns DSP may be connected to a corresponding one of the first impurity regions 111 through the landing pad LP and the storage node contact BC.

In an embodiment, the data storage pattern DSP may be a capacitor CAP including a bottom electrode BE, a dielectric layer DL, and a top electrode TE. In this case, the semiconductor memory device may be a dynamic random access memory (DRAM) device. The capacitor CAP may be connected to the first impurity region 111 of the active pattern ACT. In an embodiment, the bottom electrode BE may be in the shape of a circular pillar or a cylinder with an open top. The top electrode TE may cover the bottom electrode BE. The dielectric layer DL may be interposed between the bottom electrode BE and the top electrode TE. In an embodiment, a plurality of supporting patterns (not shown) may be interposed between the bottom electrodes BE and may prevent the bottom electrodes BE from collapsing. In an embodiment, the dielectric layer DL may be further interposed between the supporting patterns and the top electrode TE. The bottom electrodes BE may be formed of or include at least one of doped polysilicon, metal nitride materials (e.g., titanium nitride), or metallic materials (e.g., tungsten, aluminum, and copper). The top electrode TE may be formed of or include at least one of doped polycrystalline silicon, doped silicon germanium, metal nitrides (e.g., titanium nitride), or metallic materials (e.g., tungsten, aluminum, and copper). In an embodiment, the dielectric layer DL may be formed of or include at least one of silicon oxide, silicon nitride, silicon oxynitride, or high-k dielectric materials (e.g., hafnium oxide).

As another example, the data storage pattern DSP may include a magnetic tunnel junction pattern. In this case, the semiconductor memory device may be a magnetic random access memory (MRAM) device.

As other example, the data storage pattern DSP may include a phase change material or a variable resistance material. In this case, the semiconductor memory device may be a phase-change random access memory (PRAM) device or a resistive random access memory (ReRAM) device. However, the inventive concept is not limited to these examples, and the data storage pattern DSP may include various structures and/or materials which can be used to store data.

A peripheral word line (or, peripheral gate line) PWL may be disposed on the peripheral active pattern PACT. When viewed in a plan view, the peripheral word line PWL may cross the peripheral active pattern PACT, between a pair of the third impurity regions 113. The peripheral word line PWL may include a gate dielectric pattern 306, a peripheral polysilicon pattern 310p, a peripheral ohmic pattern 320p, a peripheral electrode pattern BLp, and a peripheral capping pattern 350p, which are sequentially stacked, and a peripheral spacer 355 covering side surfaces of them. The gate dielectric pattern 306 may be formed of or include at least one of silicon oxide or high-k dielectric materials. The peripheral polysilicon pattern 310p, the peripheral ohmic pattern 320p, and the peripheral electrode pattern BLp may include the same materials as the polysilicon pattern 310, the first ohmic pattern 320, and the bit line BL on the cell region CR. The peripheral capping pattern 350p may be formed of the same material as the bit line capping pattern 350 or may include at least one of elements that are included in a material of the bit line capping pattern 350. The peripheral spacer 355 may be formed of or include at least one of silicon oxide or silicon nitride and may be a single or composite layer.

A first lower insulating layer LIL1 may be provided on the peripheral region PR to cover the peripheral active pattern PACT, the device isolation pattern 120, and the peripheral word line PWL. The first lower insulating layer LIL1 may include an insulating material. As an example, the first lower insulating layer LIL1 may be formed of or include at least one of silicon oxide, silicon nitride, TEOS, or low-k dielectric materials. In an embodiment, the first lower insulating layer LIL1 may be a single layer, which is made of a single material, or a composite layer including two or more materials.

A lower contact structure LCS may be provided to penetrate the first lower insulating layer LIL1. In an embodiment, a plurality of lower contact structures LCS may be provided. Each of the lower contact structures LCS may be provided to penetrate the first lower insulating layer LIL1 in the first direction D1 and may be connected to one of the third impurity regions 113 and the peripheral electrode pattern BLp. Each of the lower contact structures LCS may be enclosed by the first lower insulating layer LIL1. In an embodiment, the lower contact structure LCS may be formed of or include the same material as the landing pad LP.

A second lower insulating layer LIL2 may cover the first lower insulating layer LIL1. The second lower insulating layer LIL2 may include an insulating material. As an example, the second lower insulating layer LIL2 may be formed of or include at least one of silicon oxide, silicon nitride, or low-k dielectric materials. In an embodiment, the second lower insulating layer LIL2 may be a single layer, which is made of a single material, or a composite layer including two or more materials.

Hereinafter, the term “semiconductor layer 500” will refer to a structure including elements, which are located in a region from the active patterns ACT to the data storage pattern DSP and from the peripheral active patterns PACT to the second lower insulating layer LIL2. The semiconductor layer 500 may correspond to the semiconductor layer 20 of FIGS. 1 to 6.

An intermediate insulating layer MIL may be provided on the cell region CR and the peripheral region PR. The intermediate insulating layer MIL may be provided on the semiconductor layer 500, in the cell region CR and the peripheral region PR. As an example, the intermediate insulating layer MIL on the cell region CR may cover the data storage pattern DSP (e.g., the capacitor CAP). The intermediate insulating layer MIL on the peripheral region PR may cover the second lower insulating layer LIL2.

In an embodiment, the intermediate insulating layer MIL may correspond to the first insulating layer 30 of FIGS. 1 to 6. Thus, the intermediate insulating layer MIL may have some technical features that are the same as or similar to those of the first insulating layer 30 described with reference to FIGS. 1 to 6.

A contact plug CPLG may be provided to penetrate the intermediate insulating layer MIL. In an embodiment, a plurality of contact plugs CPLG may be provided. The contact plug CPLG may be provided to penetrate the intermediate insulating layer MIL and may be connected to the semiconductor layer 500. In an embodiment, some of the contact plugs CPLG may be provided on the cell region CR and may be respectively connected to conductive patterns (e.g., the data storage pattern DSP, the bit line BL, and the word line WL). Others of the contact plugs CPLG may be provided on the peripheral region PR and may be respectively connected to other conductive patterns (e.g., the third impurity regions 113 and the peripheral electrode pattern BLp).

In an embodiment, the contact plug CPLG may correspond to the first conductive structure 35 of FIGS. 1 to 6. Thus, the contact plug CPLG may have some technical features that are the same as or similar to those of the first conductive structure 35 described with reference to FIGS. 1 to 6. For example, the contact plug CPLG may include a first conductive barrier pattern BP0 and a first conductive pattern CP0 formed on the first conductive barrier pattern BP0. The first conductive barrier pattern BP0 and the first conductive pattern CP0 may correspond to the first conductive barrier pattern 31 and the second conductive pattern 33 of FIGS. 1 to 6, respectively. As an example, a top surface of the contact plug CPLG may be located at a height higher than a top surface of the intermediate insulating layer MIL.

A first upper insulating layer UIL1 may cover the intermediate insulating layer MIL. The first upper insulating layer UIL1 may cover the intermediate insulating layer MIL, on the cell region CR and the peripheral region PR. In an embodiment, the first upper insulating layer UIL1 may correspond to the second insulating layer 40 of FIGS. 1 to 6. Thus, the intermediate insulating layer MIL may have some technical features that are the same as or similar to those of the second insulating layer 40 described with reference to FIGS. 1 to 6.

A first diffusion barrier layer DB1 may be interposed between the intermediate insulating layer MIL and the first upper insulating layer UIL1. In an embodiment, the first diffusion barrier layer DB1 may correspond to the diffusion barrier layer 50 of FIGS. 1, 3, 4, and 6. In this case, the first diffusion barrier layer DB1 may have some technical features that are the same as or similar to those of the diffusion barrier layer 50 described with reference to FIGS. 1, 3, 4, and 6.

As another example, the first diffusion barrier layer DB1 may not be interposed between the intermediate insulating layer MIL and the first upper insulating layer UIL1. Thus, the semiconductor device may have the structure described with reference to FIG. 2 or 5.

A first contact structure CS1 may be provided to penetrate the first upper insulating layer UIL1. In an embodiment, a plurality of first contact structures CS1 may be provided. Some of the first contact structures CS1 may be provided to penetrate the first upper insulating layer UIL1 and may be connected to corresponding ones of the contact plugs CPLG. Others of the first contact structures CS1 may be provided to penetrate the first upper insulating layer UIL1 but may not be connected to the contact plug CPLG. In an embodiment, the first contact structure CS1 may further penetrate the first diffusion barrier layer DB1.

In an embodiment, the first contact structure CS1 may correspond to the second conductive structure 45 of FIGS. 1 to 6. Thus, the first contact structure CS1 may have some technical features that are the same as or similar to those of the second conductive structure 45 described with reference to FIGS. 1 to 6. For example, the first contact structure CS1 may include a second conductive barrier pattern BP1 and a second conductive pattern CP1 formed on the second conductive barrier pattern BP1. The second conductive barrier pattern BP1 and the second conductive pattern CP1 may correspond to the second conductive barrier pattern 41 and the second conductive pattern 43 of FIGS. 1 to 6, respectively. As an example, the lowermost surface of the first contact structure CS1 may be located at a height higher than the top surface of the intermediate insulating layer MIL.

A second upper insulating layer UIL2 may cover the first upper insulating layer UIL1. As an example, a second diffusion barrier layer DB2 may be interposed between the first upper insulating layer UIL1 and the second upper insulating layer UIL2. As another example, the second upper insulating layer UIL2 may be in contact with the first upper insulating layer UIL1. The second diffusion barrier layer DB2 may not be provided or may be locally provided. A second contact structure CS2 may be provided to penetrate the second upper insulating layer UIL2 and may be connected to the first contact structure CS1. For example, the second contact structure CS2 may include a third conductive barrier pattern BP2 and a third conductive pattern CP2 formed on the third conductive barrier pattern BP2.

Although not shown, the semiconductor device may include upper insulating layers and contact structures, which are stacked to form three or more layers. As an example, a third upper insulating layer and a fourth upper insulating layer may be provided on the second upper insulating layer UIL2, and a third contact structure and a fourth contact structure may be provided to penetrate the third upper insulating layer and the fourth upper insulating layer, respectively.

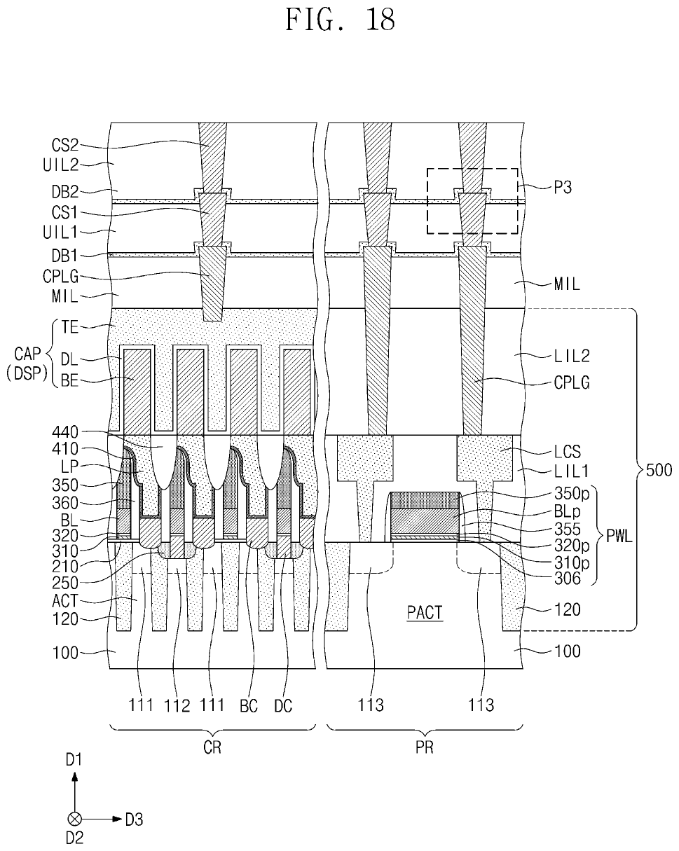

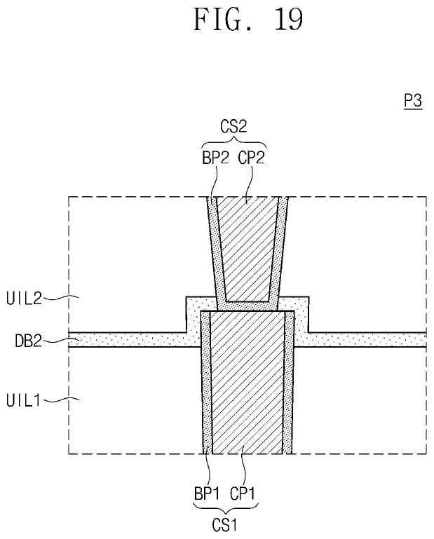

FIG. 18 is a sectional view taken along the line A-A′ of FIG. 15 according to example embodiments. FIG. 19 is an enlarged view corresponding to a portion ‘P3’ of FIG. 18 according to example embodiments. For concise description, a previously described element may be identified by the same reference number without repeating an overlapping description thereof.

Referring to FIGS. 18 and 19, the intermediate insulating layer MIL, the first upper insulating layer UIL1, the contact plug CPLG, and the first contact structure CS1 may respectively correspond to the first insulating layer 30, the second insulating layer 40, the first conductive structure 35, and the second conductive structure 45 of FIGS. 1 to 6. Furthermore, the first upper insulating layer UIL1, the second upper insulating layer UIL2, the first contact structure CS1, and the second contact structure CS2 may correspond to the first insulating layer 30, the second insulating layer 40, the first conductive structure 35, and the second conductive structure 45 of FIGS. 1 to 6.

Thus, a top surface of the first contact structure CS1 may be located at a height higher than a top surface of the first upper insulating layer UIL1. The lowermost surface of the second contact structure CS2 may be located at a height higher than the top surface of the first upper insulating layer UIL1.

The second diffusion barrier layer DB2 may correspond to the diffusion barrier layer 50 of FIGS. 1, 3, 4, and 6. Thus, the second diffusion barrier layer DB2 may have some technical features that are the same as or similar to those of the diffusion barrier layer 50 described with reference to FIGS. 1, 3, 4, and 6. In an embodiment, the first upper insulating layer UIL1 may be in contact with the second upper insulating layer UIL2. In this case, the second diffusion barrier layer DB2 may not be provided or may be locally provided.

In an embodiment, the first upper insulating layer UIL1, the second upper insulating layer UIL2, the first contact structure CS1, and the second contact structure CS2 may correspond to the first insulating layer 30, the second insulating layer 40, the first conductive structure 35, and the second conductive structure 45 of FIGS. 1 to 6. In this case, the intermediate insulating layer MIL, the first upper insulating layer UIL1, the contact plug CPLG, and the first contact structure CS1 may not correspond to the first insulating layer 30, the second insulating layer 40, the first conductive structure 35, and the second conductive structure 45 of FIGS. 1 to 6.

In an embodiment, the semiconductor device may include upper insulating layers and contact structures, which are stacked to form three or more layers and are provided to have substantially the same features as those in the embodiments described with reference to FIGS. 1 to 6.

According to an embodiment of the inventive concept, it may be possible to prevent an interface defect between a first conductive structure and a second conductive structure from spreading along a top surface of a first insulating layer. Also, it may be possible to prevent a hydrogen ion in the first insulating layer from being diffused into the second conductive structure. In the case where a second insulating layer includes a low-k dielectric material, it may be possible to reduce an effective dielectric constant of an insulating layer enclosing the conductive structures. As a result, electrical and reliability characteristics of a semiconductor device may be improved.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a semiconductor layer on a substrate;
a first insulating layer on the semiconductor layer;
a first conductive structure, which is provided to penetrate the first insulating layer in a vertical direction perpendicular to a bottom surface of the substrate and is connected to the semiconductor layer;
a second insulating layer covering the first insulating layer and the first conductive structure;
a second conductive structure, which is provided to penetrate the second insulating layer in the vertical direction and is connected to the first conductive structure; and
a diffusion barrier layer covering a top surface of the first insulating layer and extending to a side surface of the first conductive structure,
wherein the lowermost surface of the second conductive structure is located at a height higher than the top surface of the first insulating layer.

2. The semiconductor device of claim 1, wherein the lowermost surface of the second conductive structure is spaced apart from the top surface of the first insulating layer.

3. The semiconductor device of claim 1, wherein the first conductive structure and the second conductive structure comprise different materials from each other.

4. The semiconductor device of claim 1, wherein the diffusion barrier layer includes a first top surface, which extends along the top surface of the first insulating layer, and a second top surface, which is placed at a height higher than the first top surface, and
wherein the lowermost surface of the second conductive structure is located at a height higher than the first top surface of the diffusion barrier layer.

5. The semiconductor device of claim 4, wherein the lowermost surface of the second conductive structure is spaced apart from the first top surface of the diffusion barrier layer.

6. The semiconductor device of claim 1, wherein:
a top surface of the first conductive structure is located at a first level,
the first conductive structure has a first width, at the first level,
the second conductive structure has a second width, at the first level, and
the second width is equal to or different from the first width.

7. The semiconductor device of claim 1, wherein the lowermost surface of the second conductive structure is located at a height that is lower than or equal to a top surface of the first conductive structure.

8. The semiconductor device of claim 1, wherein a top surface of the first conductive structure is located at a first level, and
wherein the first insulating layer is in contact with the diffusion barrier layer, at a height lower than the first level.

9. The semiconductor device of claim 1, wherein the first insulating layer includes a hydrogen ion.

10. The semiconductor device of claim 1, wherein:
the second conductive structure is a first structure,
the semiconductor device further comprises a second structure penetrating at least a portion of the second insulating layer,
a top surface of the second structure is located at a height equal to a top surface of the first structure, and
a bottom surface of the second structure is located at a height lower than a bottom surface of the first structure and higher than the top surface of the first insulating layer.

11. A semiconductor device, comprising:
a semiconductor layer on a substrate;
a first insulating layer on the semiconductor layer;
a first conductive structure, which is provided to penetrate the first insulating layer in a vertical direction perpendicular to a bottom surface of the substrate and is connected to the semiconductor layer;
a second insulating layer covering the first insulating layer and the first conductive structure; and
a second conductive structure, which is provided to penetrate the second insulating layer in the vertical direction and is connected to the first conductive structure,
wherein the first insulating layer and the second insulating layer include different materials from each other, and
wherein the lowermost surface of the second conductive structure is spaced apart from a top surface of the first insulating layer.

12. The semiconductor device of claim 11, wherein the lowermost surface of the second conductive structure is located at a height higher than the top surface of the first insulating layer.

13. The semiconductor device of claim 11, wherein the first conductive structure and the second conductive structure include different materials from each other.

14. The semiconductor device of claim 11, wherein the first conductive structure contacts the second conductive structure at a height higher than the top surface of the first insulating layer.

15. The semiconductor device of claim 11, wherein the second insulating layer is provided to fully enclose a side surface of the second conductive structure.

16. The semiconductor device of claim 11, wherein the first insulating layer includes a hydrogen ion.

17. The semiconductor device of claim 11, wherein the second insulating layer includes a low-k dielectric material.

18. The semiconductor device of claim 11, further comprising:
a diffusion barrier layer covering the top surface of the first insulating layer and extending to a side surface of the first conductive structure.

19. A semiconductor device, comprising:
a substrate including a cell region and a peripheral region;
a semiconductor layer on the substrate;
a first insulating layer on the semiconductor layer;
a first conductive structure, which is provided to penetrate the first insulating layer in a vertical direction perpendicular to a bottom surface of the substrate and is connected to the semiconductor layer;
a second insulating layer covering the first insulating layer and the first conductive structure; and
a second conductive structure, which is provided to penetrate the second insulating layer in the vertical direction and is connected to the first conductive structure,
wherein the semiconductor layer comprises:
an active pattern on the cell region;
a word line crossing the active pattern;
a bit line extending in a direction crossing the word line;
a capacitor connected to the active pattern, the capacitor comprising a bottom electrode, a top electrode on the bottom electrode, and a dielectric layer between the bottom and top electrodes;
a peripheral active pattern on the peripheral region; and
a peripheral word line on the peripheral active pattern,
wherein the first insulating layer and the second insulating layer include different materials from each other, and
wherein the lowermost surface of the second conductive structure is spaced apart from a top surface of the first insulating layer.

20. The semiconductor device of claim 19, further comprising:
an interlayer insulating layer covering the second insulating layer; and
a contact structure, which is provided to penetrate the interlayer insulating layer in the vertical direction and is connected to the second conductive structure.
